(19) United States
(12) Patent Application Publication
(10) Pub. No.: US 2005/0199280 A1
(43) Pub. Date: Sep. 15, 2005

(54) Solar battery

(76) Inventor: George R. Royer, Toledo, OH (US)

Correspondence Address: George R. Royer;Suite 416, 316 N. Michigan Street, Toledo, OH, 43614, US

(21) Appl. No.: 10/798,803

(22) Filed: Mar. 12, 2004

(51) Int. Cl. H01L 31/00

(52) U.S. Cl. 136/255; 136/252; 136/256

(57) ABSTRACT

The subject invention is an improved solar battery having a first surface and a second surface, which battery utilized the radiant energy impact of sunlight on the first surface for energy input into the battery and another energy source input on its second surface for additional energy input into the battery member such that the solar battery has additional energy input to increase its electrical or other output.

### DISCUSSION OF PRIOR ART AND BACKGROUND OF INVENTION

The applicable art area herewith relates to solar powered batteries of the type that utilize one or more semiconductor features to transform solar energy directly into electricity. A commonly used component of such solar batteries is the silicon photovoltaic cell. Individual cells of such type may be connected in series or parallel for such electrical generation purposes.

Solar batteries, as presently structured in the art, are only moderately effective for producing significant electrical energy output. Thus, one of the major problems encountered with existing solar batteries if the output efficiency aspect. Specifically, one aspect that limits the efficiency of solar batteries is the fact that the solar energy utilized generally can be received on one surface only of the battery. By this limited solar exposure, the energy input into the battery is essentially limited, and the electrical or other output of the battery is obviously limited commensurably.

By reason of the foregoing, a solar battery that has means to absorb additional energy sources on additional surfaces of the battery, in order to supplement the solar energy received on the first surface of the battery would be relatively more efficient. Stated alternately, a solar battery that is capable of utilized solar energy impacting on its upper surface may yield a higher output of electrical energy by impacting additional energy sources on the lower surface or other surfaces of the solar battery. This additional energy input on the lower or other surface of the battery may comprise solar rays or other energy sources, thereby increasing the output of the battery.

Thus, as stated, the purpose herein is to improve the efficiency or electrical output of a solar battery and the objects herein are directed accordingly.

### OBJECTS OF INVENTION

It is an object of the subject invention to provide an improved solar battery;

An additional object of the subject invention is to provide an improved battery using multiple sources of energy to produce electricity;

Another object of the subject invention is to provide an improved method for improving the effectiveness of a solar battery;

Another service of the subject invention is to provide a battery that utilized multiple energy sources for its power;

Still another object of the subject invention is to provide a supplementary energy input mechanism for a solar powered battery to help increase the output of the battery;

A further object of the subject invention is to provide a means to supplement the power input on a solar powered battery;

Yet another object of the subject invention is to provide a mechanism for improving the electrical output of a solar powered battery;

A further object of the subject invention is to provide a device that enables a solar battery to receive and utilize multiple energy sources;

Other and further objects of the subject invention will become apparent on a reading of the specification in conjunction with the claims and drawings.

### BRIEF DESCRIPTION OF THE DRAWINGS

FIG. 1 is a side elevational view of the subject invention in section of a conventional solar battery construction;

FIG. 2 is a side elevational view in section of one embodiment of the subject invention;

FIG. 3 is a side elevational view in cross sectional configuration of another embodiment of the subject invention in cross section.

### DESCRIPTION OF GENERAL EMBODIMENT AND SUMMARY OF INVENTION

The subject invention is an improved solar battery having a first surface and a second surface, which battery utilized the radiant energy impact of sunlight on the first surface for energy input into the battery and another energy source input on its second surface for additional energy input into the battery member such that the solar battery has additional energy input to increase its electrical or other output.

Alternately stated, the subject invention is an improved solar battery having a first surface and a second surface which battery utilized the radiant energy impact of sunlight on the first surface and the piezoelectric energy effect presence on the second surface for additional energy input into the battery member. Other energy sources can be used on such second surface.

In general, the subject invention is based on a solar battery having a first surface, which could be the upper surface and a second surface, which could be the lower surface opposite to the first surface with the upper surface generally being adapted and structured to absorb solar energy as the primary power input into the solar battery. The concept covered in this patent application involves means to impact additional energy sources on the lower surface of the battery, or more specifically the surface opposite to the solar energy receiving surface of the battery in order to provide supplementary energy input into the battery or semiconductor member. Surfaces on the solar battery other than the lower surface may be used for purposes or receiving the additional energy surface. This additional energy input ma comprise variant form of externally imposed energy such as redirected solar rays, pressure, or other external energy means. By such additional energy input, the electrical output of the battery will be increased accordingly in some direct proportion to the amount of supplementary energy impacted on the battery. To a certain, but limited extent, the concept of this invention may be equally applicable to semiconductors or other devices related to solar batteries.

As a matter of base background, in the conventionally structured solar battery is the upper surface thereof is the adapted and approximately structured and composed as the solar energy receptory surface. More specifically, the upper surface is adapted to receive the energy, input of sunlight and absorb same for power of the solar battery.

While the upper portion of a solar cell or solar battery may be comprised of any of several different substances, one of the most common elements used is the silicon with a positive-negative junction (p-n junction) formed as the basic component of the solar battery. In this p-n junction if silicon is used, a positive type silicon (p-type silicon) component is generally formed by adding such elements as boron, aluminum, or gallium, and as a result thereof electric current in such p-type silicon is carried by free holes, which are atoms missing an electron causing the charges of the atom to be positive. These positively charged atoms are free to move throughout the silicon layer. On the other hand, n-type (negative type) silicons usually formed by adding minimal amounts of arsenic to the silicon help to create free electrons which are able to move about in the n-type silicon material.

The face between layers of p-type silicon and n-type silicon is referred to as a p-n junction. This p-n junction area of the semiconductor has a permanent dipole charge layer with a relatively high electric field. This high electrical field forces moveable electrons towards the positively charges portion of the battery. Positively charges particles move towards the negatively charged portion of the battery. The positive charges are essentially atoms, which as stated are missing an electron towards the p-type silicon and create positively charged atoms of the substance or element n which is used to dope the n-type silicon, such as arsenic. As a net result of this creation of the negatively charges substances in the p-type silicon and positively charged atoms in the n-type silicon an electrical barrier field is created which stops the remaining oppositely charges particles in the p-type and n-type silicon form.

### DESCRIPTION OF A SPECIFIC EMBODIMENT OF SUBJECT INVENTION

In describing the preferred embodiment of the subject invention, it is to be stressed that the following description is only one embodiment of several that are within the overall scope of the subject invention. Therefore, the following description of such a specific embodiment shall not be considered as limiting the scope of the invention herein as presented in this application and the claim appended hereto.

In describing the preferred embodiment or embodiments of the subject invention, the semiconductor or solar battery member to which the concepts herein apply has a solar receptor surface, which surface swill be referred to as the upper surface for description purposes. The surface of the semiconductor opposite to the solar receptor surface will be referred to as the “lower” surface. Moreover, the words “solar rays”, “sunlight”, “solar energy”, “solar radiation” will be used interchangeably as having a common reference to sun generated energy received on earth's surface. Moreover, the words “solar battery” will be used interchangeable as reverenced herein to “solar cell” or related semiconductors.

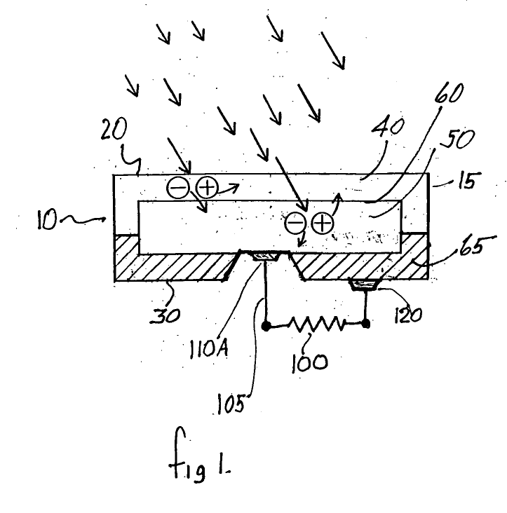

Referring now to the drawings in which one preferred embodiment of the subject invention is shown, particular attention is drawn to FIG. 1. Shown in FIG. 1 is the standard configuration of a conventional solar battery 10, which is comprised of a base member 15, has an upper surface 20, and a lower surface 30. The upper surface 20 and the lower surface 30 are approximately equivalent in shape and surface area with such respective surfaces being the two largest surfaces of the rectangularly shaped base member 15. In this respect, the base member 15 may be other than the rectangular shape shown in the drawings, so long as it has solar receiving surfaces. And finally, it is not essential the upper and lower surfaces of the solar battery 10 be of equal size or shape. Moreover, it is not essential that the energy receiving surface be like the second energy receiving surface.

In the conventionally structured solar battery, as stated, the upper surface thereof is adapted and appropriately structured and comprised as the solar energy reception surface. More specifically, in the subject solar battery 10 the upper surface 20 is adapted to receive the energy input of sunlight and absorb same for providing power to the solar battery. For this purpose, the upper portion 40 of the solar battery 10, including the upper surface, may be comprised of any one of several substances, and one of the most commonly used is silicon, as represented in FIG. 1. Thus, more specifically, as in the usual constructional arrangement of solar batteries of this type, solar battery 10 has an upper layered portion 40, including the upper surface 20, which is comprised of a positive type of silicon or a layer of silicon having net positive charges. Immediately adjacent or underneath the upper portion 40 is an intermediate layer 50 of silicon having a net negative charge, or n-type silicon. In the usual constructional arrangement the p-type silicon portion 40 surrounds the n-type silicon layer 50 in a sandwich fashion, as seen in the drawings so that the n-type silicon layer is completely enclosed in the p-type silicon layer. As a consequence of this latter arrangement, a lower portion 65 also comprising p-type silicon exists on the portion of the solar battery 10.

The interstitial face between the layered portion of p-type silicon 40 and n-type silicon 50 is thus described as the p-n junction zone 60. This p-n junction area 60 of the solar battery 10 has a permanent dipole charge layer with a relatively high electric field. This high electrical field forces moveable electrons from the n-type portion 50 towards the positively charged p-type portion 40 of the battery 10. In this process, positively charged particles move from the p-type portion 40 towards the negatively charged n-type portion 50. In this respect, the positive charges are essentially atoms that are missing an electron, while the negative charged electrons are those that have not bonded to an atom. The material in n-type portion 40 sandwiched in the center of battery 10, while the electrons tend to move into the p-type silicon portion 40 surrounding the n-type silicon portion 50, as graphically represented in FIG. 1. The net effect of this process is an electrical barrier or field being created at the p-n junction 60.

An electrical load 100 is connected in a circuit 105 between positive terminals 110A and 110B and a negative terminal 120, and electric current will pass as a result through the circuit 105 as a result of the electrical field created, which current can be utilized accordingly. The electrical power generated in circuit 105 is commensurate to the input of the amount of the solar energy impinging on the upper surface 20 of the battery member 10.

The solar battery 10 thus described above is a conventionally structured solar cell member that is adapted to receive solar energy on the upper surface 20 only. As can be readily understood, the reception of solar energy on a given surface is at any one time basically undirectional and as a consequence when sunlight is received on a solar battery the resultant impingement of light is usually against one surface only. If, on the other hand, additional solar ray or other energy sources can be redirected to an additional surface of solar battery 10, such as the lower surface 30, which is generally equally as large in area as the upper surface 20, additional energy input into the solar battery 10 can be achieved. This latter concept then forms the focus and thrust of the invention herein.

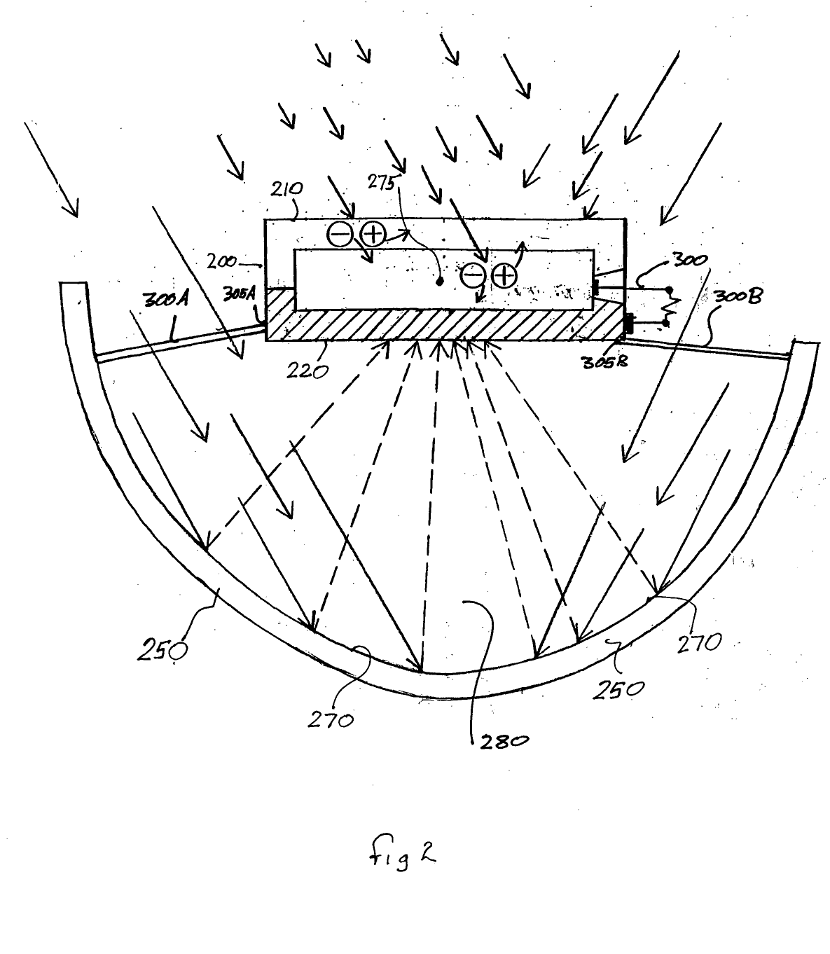

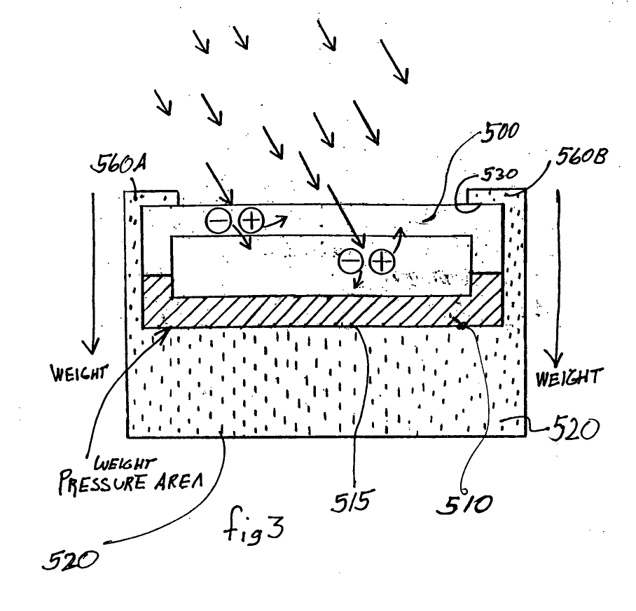

One of the means used to impart additional energy into the solar battery is through additional solar energy being directed to the lower outer surface 30 of the solar battery 10 such as by redirected or reflected sunlight on such lower surface. This application will incorporate description of one embodiment using redirected solar rays on the lower surface 30 of the solar battery 10 as a means of additional energy for the solar battery 10. This particular embodiment is shown in FIG. 2, while shown in FIGS. 3 and 4 will be an embodiment using pressure as the force to be directed on the lower surface 30 to achieve additional energy input into the solar battery 10. Other additional energy sources may be used to provide energy input into the lower surface 30 of the solar battery 10 and thus description of only one embodiment shall not be construed as limiting the scope of the invention herein.

It is important to note at this juncture that in using additional energy sources, such as additional sunlight to help power the solar battery surfaces other than the lower surface 30 of the solar battery 10 may be utilized for this purpose. In this latter regard, the structuring of a solar battery may be a source configuration that the base member be other than a flat, rectangular member.

Referring now to FIG. 2 which shows a structural arrangement which incorporates features of the subject invention, in which additional solar rays are directed to the lower surface 30 as well as upper surface 20 of solar battery member. Specifically shown in FIG. 2 is solar battery 200 which is a flat member having an upper surface 210 and a lower surface 220 which two surfaces have the largest outer surface area of such solar battery 200. As can be determined from the foregoing discussion, the upper surface 210 of solar battery 200 is the primary solar energy receptor surface. In the embodiment shown in FIG. 2, lower surface 220 is also structured as a solar energy receptor surface, specifically adapted for receiving quantities of solar energy thereon, as more fully discussed below.

As indicated above, the structural arrangement of solar battery 200 is basically identical to solar battery 10 described above and shown in FIG. 1. What is different between solar battery 10, shown in FIG. 1, and solar battery 200, shown in FIG. 2 is that the lower surface 220 of solar battery is specifically structured and composed to receive solar energy on such lower surface thereof.

More particularly, in the solar battery embodiment shown in FIG. 2 of the drawings, the solar battery 200 is equipped with means to receive solar heat as solar radiation on the lower or rear surface 220 of the battery, as well as on the upper surface 210 thereof, so that such additional solar energy will yield energy input into the solar battery in addition to the solar energy impinged on the front or upper surface 210. By this arrangement, the energy output of the solar battery 200 set forth in FIG. 2 will be theoretically increased to some appreciable degree in proportion to the additional solar energy input or the lower surface 220. As shown in FIG. 2, the solar battery 200 is positioned with means to receive solar heat on the under surface 210 of the solar battery 200, as well as onto the lower surface 220. The means to receive additional solar energy on the lower surface 220 includes among other potential methods use of a parabolic reflector 250 which is positioned in back of the solar battery 200, away from the sun, but directed towards the sun so as to receive solar rays into the parabolic reflector which is positioned to redirect such solar energy back to the lower surface 220 of the solar battery 200.

Before proceeding with the following discussion, it should be emphasized that the use of a parabolic reflector may be only one of several means to direct solar energy to the lower surface 220 of the solar battery 200, as other means may be used to redirect solar energy to such lower surface. In this respect, such other means as discussed above, can employ or utilized for redirecting sunlight or other similar means. With this background the use of the parabolic reflector 250 is one specific method of collecting and imparting additional solar energy for input onto the lower surface 220 of the solar battery 200. As seen parabolic solar collector 250 has a parabolically shaped interior surface 270 adapted to receive and reflect solar energy from such parabolic surface 270. As is well known, a parabolic shape will receive and collect solar rays over substantially all points of the inner parabolic surface 270 and reflect all such collected solar rays back to a common spatially located concentration point 275 generally located within the confines of the parabollically shaped interior spatial area 280 of the parabolic collector, as schematically represented in FIG. 2. As can be seen schematically in FIG. 2, the parabolic solar collector 250 will be optimally strategically placed so that the spatially located concentration point 275 will be located in a real and imaginary focus above lower surface 220 of the solar battery 200 so that the refracted solar rays will connect more evenly over the lower surface 220 of the solar collector 220.

More particularly for purposes of maximizing the input of the solar energy collected by the parabolic reflector 250, onto the lower surface 220 of the solar battery 200, such lower surface 220 of the solar battery 200 is juxtaposed or otherwise positioned just adjacent to or near the common concentration point 270 where the solar rays collected in parabolic reflector 250 is concentrated. This positioning of the lower surface 220 of solar battery 200 will enable such bottom surface 220 to receive a greater spread of solar rays over the lower surface 220 from the parabolic reflector 260. For this positioning purpose, the solar battery 200 can, in one embodiment be positioned to be affixed by support bar members 300A and 300B affixed on the inner ends 305A and 305B to opposing ends of the solar battery, which support members are affixed on their outer ends 310A and 310B to diametrically opposing positions on the parabolic collector 250. These connecting support members 300A and 300B should be of minimal thickness or girth so as not to interfere significantly with the passage of solar rays into the parabolic collector 250 and the interior surface thereof.

Operationally and structurally, the solar battery 200 should be sized a given length that will enable it to be positioned in the upper portion of the interior spatial area 280 of the parabolic collector 250 with enough spatial clearance around the solar battery to permit passage of enough solar rays around the battery 200 to strike the interior surface of the collector for these rays to be redirected back towards the common concentration or focus point 275 in sufficient quantities to provide some significant energy input to the lower surface 220 of the battery 200.

With the lower surface 220 of the solar battery being position just a minimal distance down and away from the common focus point 275, the input of any solar energy reflected into the parabolic reflector 250 will be optimally absorbed by the lower surface 220 of solar battery 200.

As a viable alternative, when using the parabolic reflector 250 in conjunction with solar battery, a variation may employ a mechanism to be used to rotate the parabolic collector 250 to move with the sun to keep it positioned constantly towards the sun. This would turn move the upper surface 210 of the solar battery 200 towards the sun as time progresses in the day, since the solar battery is attached to the parabolic reflector 250, as seen in FIG. 2. This movement of the collector 250 will thus permit the affixed solar battery 200 to be moved in concert with the sun's diurnal movements.

By imposing the additional solar energy, as discussed above, on the bottom surface 210 of the solar battery 200, the solar battery will now have solar energy imposing both on the upper surface 210 and the bottom surface 230 to energize the solar battery. By this relationship, the solar battery 200 structured as a p-n-p junction cell, will be equipped with p-type silicon or other suitable substances, on both the upper surface and lower surface positions of the solar battery. With this later arrangement, both p-type surfaces, upper and lower, will react to the solar energy to produce electrical energy. In this use of two flanking p-type surfaces, the cell will react to the solar energy impinging on both surfaces to produce electrical energy. In the use of two flanking p-type silicon layers, or alternately using a n-p-n cell arrangement the electrical circuiting 300 to the loan are preferably positioned on one side or lateral surfaces of the solar battery 200, as seen in FIG. 2.

As noted above, other means can be used to direct solar energy on the lower surface of the battery. Thus, description of use of a parabolic reflector mechanism is only one of said means to accomplish same.

In still another embodiment of the subject invention as seen in FIG. 3 is a solar battery 500 provided with a lower portion 510 being comprised of a substance that is sensitive to or capable of producing a peizoelectric electrical effect. Such structuring will yield electrical current under with certain conditions. Examples of peizoelectric substances that can be used in conjunction with the subject invention include crystalline quartz, rochelee salt, barium titanic, among other material that are susceptible to electrical pressure generated reflectors, as more fully described below.

In this regard, it is known that the process of applying pressure that is mechanical stress yields in certain dielectric crystalline substances what is referred to as an electrical polarization. This electrical polarization is generally commensurate to the pressure applied. Specifically, in such other embodiment of the subject invention, as seen in FIG. 3, a solar battery 500 is provided with a lower portion 510 being comprised of a substance that is sensitive to or capable of producing a piezoelectric electric effect. Specifically, in this alternate embodiment of the subject invention, as seen in FIG. 3 a solar battery 500 provided with a lower portion 510 being comprised of a substance that is sensitive to or capable of producing a peizoelectric electrical effect. Such structuring will yield electrical current under certain pressure conditions. Examples of peizoelectric substances that can be used in conjunction with the subject invention include crystalline quartz, rochelee salt, barium titanic, among other material that are susceptible to electrical pressure generated reflectors, as more fully described below. In this regard, it is known that the process of applying pressure that is mechanical stress yields in certain dielectric crystalline substances what is referred to as an electrical polarization. This electrical polarization is generally commensurate to the pressure applied.

More particularly, the lower surface 510 of solar battery 500 is adapted to pressure for electrical energy generating purposes. The pressure imposed on the plezelectrically susceptible material on the lower surface portion 515 of the solar battery 500 will yield electrical current by the imposition of such pressure. The resultant electrical polarization is generally commensurate to the pressure applied to the surface of the crystalline substance, and under certain circumstances produces a voltage across the crystal. Moreover, under situation wherein the crystal or other plezelectrically substance is short circuited an electrical flow is produced during periods of short circuitry. Thus, the application of pressure such as weighting downwardly the solar battery 500 from above with the pressure of the weighting means, such as weight 520 being directed to the lower surface 510 of the solar battery 500 will cause some prezoelectic effort on the lower portions of the solar battery 500. Such weighing means can be in the form of a weight 520 with arms 560A and 560B attached to the upper surface 530 of the solar battery 500 and causing the weight to exert pressure on the lower surface 510 of the solar battery 500 to create a prezoelectric effect to supplement the solar energy on the upper surface.

1. A solar battery having a first surface and a second surface opposing said first surface, said solar battery comprising:
(a) a first surface, said first surface portion on said battery adapted to be faced towards the sun to receive solar energy on such upper surface, said first surface being adapted to receive solar energy therein;
(b) an upper portion area on said solar battery said upper surface position having a net positive charge, said upper portion being position just adjacent and under said first surface portion;
(c) a second surface portion on said solar battery said lower surface portion being positioned opposite to and facing away from said first surface position;
(d) a lower portion comprising on said solar battery, said lower surface portion having a net positive charge, said lower surface portion being adjacent said second surface portion said lower surface portion being adapted to receive solar energy input for imparting energy into said solar battery;
(e) solar energy direction means positioned to redirect solar rays to said second surface of said solar battery;
(f) an intermediate portion in said solar battery disposed between said upper portion and said lower portion, said intermediate portion being comprised a net negative charge.

2. A solar battery having a first surface and a second surface opposing said first surface, said solar battery comprising:
(a) a first surface, said first surface portion on said battery adapted to be faced towards the sun to receive solar energy on such upper surface, said first surface being adapted to receive solar energy therein;
(b) an upper portion area on said solar battery said upper surface position having a net negative charge, said upper portion being position just adjacent and under said first surface portion;
(c) a second surface portion on said solar battery said lower surface portion being positioned opposite to and facing away from said first surface position;
(d) a lower portion comprising on said solar battery, said lower surface portion having a net negative charge, said lower surface portion being adjacent said second surface portion said lower surface portion being adapted to receive solar energy input for imparting energy into said solar battery;
(e) solar energy direction means positioned to redirect solar rays to said second surface of said solar battery;
(f) an intermediate portion in said solar battery disposed between said upper portion and said lower portion, said intermediate portion being comprised a net positive charge.

3. A solar battery adapted to receive solar energy for energizing the solar battery for eventual conversion of the solar energy to electricity comprising a solar battery having a first surface for receiving solar energy for energy conversion and a second surface for receiving and using a second source of energy to supplement the solar energy input into the solar battery.

4. A solar battery having a plurality of surface areas comprising:
(a) a first surface area, said first surface portion being a solar energy receptive surface;
(b) a second surface area being a solar energy receptive surface;
(c) a first inner portion area within said solar battery, said first inner portion being positioned just adjacent to said first surface portion, said first inner portion being comprised of an electrical semi-conductor substance comprised of a net positive electrical charge;
(d) a second inner portion within said solar battery, said second inner portion being comprised of an electrical semi-conductor substance comprised of a net positive charge, said second inner portion being positioned just adjacent against said second surface area;
(e) an intermediate portion within solar battery disposed between said first inner portion and said second inner portion where the said solar battery said intermediate portion being comprised of an electrical semi-conductor material comprised of a net negative charge.

5. a first surface area, said first surface portion being a solar energy receptive surface;
(b) a second surface area being a solar energy receptive surface;
(c) a first inner portion area within said solar battery, said first inner portion being positioned just adjacent to said first surface portion, said first inner portion being comprised of an electrical semi-conductor substance comprised of a net negative electrical charge;
(d) a second inner portion within said solar battery, said second inner portion being comprised of an electrical semi-conductor substance comprised of a net negative charge, said second inner portion being positioned just adjacent against said second surface area;
(e) an intermediate portion within solar battery disposed between said first inner portion and said second inner portion where the said solar battery said intermediate portion being comprised of an electrical semi-conductor material comprised of a net positive charge.
